(19) United States
(12) Patent Application Publication
(10) Pub. No.: US 2025/0176312 A1
(43) Pub. Date: May 29, 2025

(54) MICRO LED ELEMENT, MICRO LED DISPLAY PANEL AND DISPLAY DEVICE

(71) Applicant: JADE BIRD DISPLAY (SHANGHAI) LIMITED, SHANGHAI (CN)

(72) Inventors: Weisin TAN, Shanghai (CN); Zhichen GU, Shanghai (CN); Qunchao XU, Shanghai (CN)

(21) Appl. No.: 18/954,545

(22) Filed: Nov. 21, 2024

(30) Foreign Application Priority Data
Nov. 24, 2023 (WO) PCT/CN2023/133965

(51) Int. Cl. H01L 33/00; H01L 25/16; H01L 33/14; H01L 33/20

(52) U.S. Cl. CPC H10H 20/052; H01L 25/167; H10H 20/816; H10H 20/819

(57) ABSTRACT

A micro LED element includes a mesa including a first semiconductor layer, an intermediate layer, and a second semiconductor layer stacked from top down, wherein the mesa is divided into two stages at a side of the intermediate layer, and the intermediate layer includes: a light emitting layer; and a third semiconductor layer disposed on a surface of the light emitting layer, wherein the third semiconductor layer is exposed to the outside of the mesa to have an exposed surface relative to the mesa; and a Schottky metal layer disposed on the exposed surface, wherein the Schottky metal layer creates a depletion region in the light emitting layer.

### CROSS-REFERENCE TO RELATED APPLICATIONS

This disclosure claims the benefits of priority to PCT Application No. PCT/CN2023/133965, filed on Nov. 24, 2023, which is incorporated herein by reference in its entirety.

### TECHNICAL FIELD

The present disclosure generally relates to micro display technology, and more particularly, to a micro light emitting diode (LED) element, a micro LED display panel, and a display device.

### BACKGROUND

Inorganic micro pixel light emitting diodes, also referred to as micro light emitting diodes, micro LEDs, or u-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuit (IC) back panel. Each pixel of the micro LED display panel is formed by one or more micro LEDs. The micro LED display panel can be a mono-color or multi-color panel. In particular, for a multi-color LED panel, each pixel may further include multiple sub-pixels formed by multiple micro LEDs, each of which corresponds to a different color. For example, three micro LEDs respectively corresponding to red, green, and blue colors may be superimposed to form one pixel. The different colors can be mixed to produce a broad array of colors.

Nowadays, the size of the mesa in a micro LED may be less than 5 μm, and mesas are usually formed by etching. Etching in such a small size would inevitably damage the mesa edges of micro LEDs. Such damage may cause the micro LEDs to suffer from low efficiency due to carriers' non-radiative recombination on the mesa edges of micro LEDs. This non-radiative recombination does not generate light for displaying but only useless heat.

Therefore, there is a need for improving the lighting efficiency of micro LEDs.

### SUMMARY OF THE DISCLOSURE

Some embodiments of the present disclosure provide a micro LED element. The micro LED element includes a mesa including a first semiconductor layer, an intermediate layer, and a second semiconductor layer stacked from top down, wherein the mesa is divided into two stages at a side of the intermediate layer, the intermediate layer including: a light emitting layer; and a third semiconductor layer disposed on a surface of the light emitting layer, wherein the third semiconductor layer is exposed to an outside of the mesa to have an exposed surface relative to the mesa; and a Schottky metal layer disposed on the exposed surface, wherein the Schottky metal layer creates a depletion region in the light emitting layer.

Some embodiments of the present disclosure provide a micro LED display panel. The micro LED display panel includes an integrated circuit (IC) backplane; and a plurality of micro LED elements according to any of the micro LED elements described above, wherein each of the plurality of micro LED elements is disposed on a top surface of the IC backplane.

Some embodiments of the present disclosure provide a micro LED display panel. The micro LED display panel includes an IC backplane; a plurality of micro LED elements disposed on a top surface of the IC backplane, wherein each of the plurality of micro LED elements includes: a mesa including a first semiconductor layer, an intermediate layer, and a second semiconductor layer stacked from top down, wherein the mesa is divided into two stages at a side of intermediate layer, and the intermediate layer includes: a light emitting layer; and a third semiconductor layer disposed on a surface of the light emitting layer, wherein the third semiconductor layer is exposed to the outside of the mesa to have an exposed surface relative to the mesa; a passivation layer formed on a sidewall surface of the mesa; and an insulating layer formed on the top surface of the IC backplane between each of the plurality of micro LED elements; and a Schottky metal layer disposed on the exposed surface, on the insulating layer and a surface of the passivation layer of each of the plurality of micro LED elements, wherein the Schottky metal layer creates a depletion region in the light emitting layer of each of the plurality of micro LED elements.

Some embodiments of the present disclosure provide a micro LED display device. The micro LED display device includes any of the micro LED display panels described above.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a sectional view of an exemplary micro LED element, according to some embodiments of the present disclosure.

FIG. 2 illustrates a structural diagram showing a sectional view of another exemplary micro LED element, according to some embodiments of the present disclosure.

FIG. 3 illustrates a structural diagram showing a sectional view of another exemplary micro LED element, according to some embodiments of the present disclosure.

FIG. 4 illustrates a structural diagram showing a sectional view of another exemplary micro LED element, according to some embodiments of the present disclosure.

FIG. 5 illustrates a structural diagram showing a sectional view of an exemplary micro LED element including a depletion region, according to some embodiments of the present disclosure.

FIG. 6 illustrates a structural diagram showing a sectional view of an exemplary micro LED display panel, according to some embodiments of the present disclosure.

FIG. 7 illustrates a structural diagram showing a top view of an exemplary micro LED display panel, according to some embodiments of the present disclosure.

FIG. 8 illustrates an exemplary display device, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

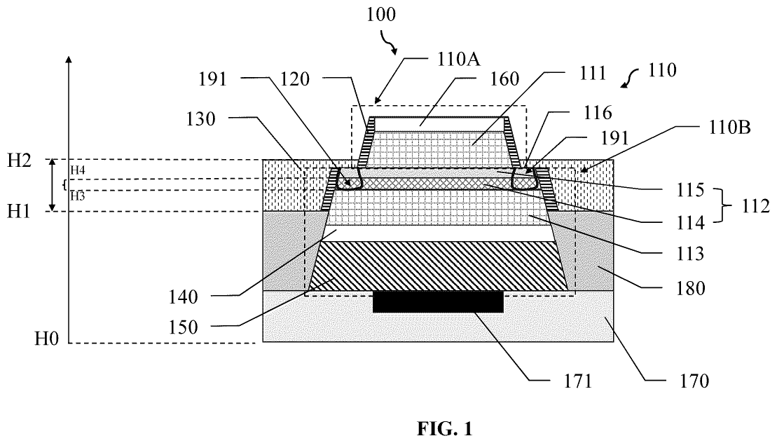

FIG. 1 illustrates a structural diagram showing a sectional view of an exemplary micro LED element 100, according to some embodiments of the present disclosure. Referring to FIG. 1, micro LED element 100 includes a mesa 110, which includes a first semiconductor layer 111, an intermediate layer 112, and a second semiconductor layer 113. First semiconductor layer 111, intermediate layer 112, and second semiconductor layer 113 are stacked from top down to form mesa 110. Micro LED element 100 may also include other components which are omitted here for not obscuring the principle of the present disclosure. As can be seen from FIG. 1, mesa 110 includes two stages. A first stage 110A includes first semiconductor layer 111, and a second stage 110B includes intermediate layer 112 and second semiconductor layer 113. The interface or border between first stage 110A and second stage 110B is a surface of intermediate layer 112. Specifically, the interface between first stage 110A and second stage 110B in FIG. 1 is the top surface of intermediate layer 112. As can be appreciated, first stage 110A and second stage 110B have substantially different cross-sectional sizes at the interface.

As shown in FIG. 1, intermediate layer 112 includes a light emitting layer 114 and a third semiconductor layer also referred to herein as a low doped layer 115. The stacking order of light emitting layer 114 and low doped layer 115 between first semiconductor layer 111 and second semiconductor layer 113 can be varied according to actual needs. To avoid direct exposure to the outside, light emitting layer 114 can be covered by low doped layer 115 as viewed from the outside. That is, a surface of low doped layer 115 plays the role of the interface, as mentioned above. As low doped layer 115 is disposed on a surface of light emitting layer 114 (i.e., on a top surface of light emitting layer 114 as shown in FIG. 1), a portion of low doped layer 115 is exposed on the outside of mesa 110 to have an upward (vertical) facing exposed surface 116 relative to mesa 110. A width of exposed surface 116 can be between 0.2 μm to 10 μm. The upward direction relative to mesa 110 is also a direction in which light from light emitting layer 114 is intended to be emitted. Low doped layer 115 serves as a thin dielectric layer for a Schottky metal layer 130 that is disposed on exposed surface 116, as described below. A height of low doped layer 115 is in a range of 5 nm to 50 nm. By this arrangement, Schottky metal layer 130 can create a depletion region that extends into light emitting layer 114 as more fully explained below. In addition, low doped layer 115 has the same doping type as first semiconductor layer 111, and low doped layer 115 has a lower doping concentration than first semiconductor layer 111, and is accordingly referred to herein as “low doped”. For example, if first semiconductor layer 111 is an N-type layer formed by doping Si substrate with a doping concentration of 10¹⁸/cm³, then low doped layer 115 can be an N-type layer formed by doping Si substrate with a doping concentration of 10¹⁷/cm³ or lower.

As can be seen in FIG. 1, a sidewall of mesa 110 is inclined. In some embodiments, referring to FIG. 1, a diameter of a top surface of mesa 110 is smaller than a diameter of a bottom surface of mesa 110. A cross-sectional size of mesa 110 decreases with increasing height of mesa 110 at each of the two stages 110A and 110B. That is, the sidewall of mesa 110 inclines so that mesa 110 gradually becomes narrower from bottom to top at each stage.

The inclined sidewall can be found in other embodiments described below in conjunction with other figures. As mesa 110 can be formed by etching at certain angles, the width of different layers will be different due to the etching mechanism. In an etching process, the upper layers (or upper stage) are basically narrower than the lower layers (or lower stage).

Still referring to FIG. 1, mesa 110 further includes a first transparent conductive layer 140. Second semiconductor layer 113 is formed on a top surface of first transparent conductive layer 140. Intermediate layer 112 is formed on second semiconductor layer 113, and first semiconductor layer 111 is formed on intermediate layer 112. Second semiconductor layer 113 can be a P-type epitaxial layer or an N-type epitaxial layer. First semiconductor layer 111 is an N-type epitaxial layer or a P-type epitaxial layer. A material of first semiconductor layer 111 is selected from one or more of GaN, InGaN, AlInGaN, AlGaN, GaP, AlGaInP, or AlInP. Light emitting layer 114 in intermediate layer 112 is a quantum well layer. A material of light emitting layer 114 is selected from one or more of InGaN, AlGaN, AlInGaN, InGaP or AlGaInP. First semiconductor layer 111 and second semiconductor layer 113 are doped to have opposite conductivity types. That is, if first semiconductor layer 111 is a P-type epitaxial layer, then second semiconductor layer 113 is an N-type epitaxial layer; and if first semiconductor layer 111 is an N-type epitaxial layer, then second semiconductor layer 113 is a P-type epitaxial layer. A material of second semiconductor layer 113 is selected from one or more of AllnP, AlGaInP, GaP, GaN, InGaN, AlInGaN or AlGaN.

Micro LED element 100 further includes a passivation layer 120 formed on a sidewall surface of mesa 110, at each of two stages 110A and 110B. The thickness of passivation layer 120 is in the range of 10 nm to 200 nm. An exemplary thickness of passivation layer 120 can be 15 nm, 20 nm, 25 nm, 30 nm, 35 nm, 40 nm, 45 nm, or 50 nm. In some examples, passivation layer 120 is an ALD (Atomic Layer Deposition)-based layer. A material of passivation layer 120 can be selected from one or more of Al₂O₃, HfN, or SiN. Passivation layer 120 encapsulates the components inside and provides insulation from the outside.

Micro LED element 100 further includes Schottky metal layer 130 disposed on exposed surface 116. Schottky metal layer 130 can create a depletion region 191 in light emitting layer 114 and that may extend into other layers, as described below. In FIG. 1, depletion region 191 covers an edge of mesa 110 in light emitting layer 114. Depletion region 191 is also created in part of low doped layer 115. In some cases, Schottky metal layer 130 can be of the same type (e.g., N-type, P-type) as second semiconductor layer 113. In this situation, Schottky metal layer 130 can be further biased by a voltage, which will be described below. In some other cases, Schottky metal layer 130 can be of a different type than second semiconductor layer 113. In this situation, Schottky metal layer 130 may not be biased.

Although Schottky metal layer 130 disposed on exposed surface 116 is sufficient to create depletion region 191, as shown in FIG. 1, Schottky metal layer 130 can be further disposed on a surface of passivation layer 120, for depositing Schottky metal layer 130 in a more practical process. Specifically, the height of Schottky metal layer 130 spans across at least a part of the height of light emitting layer 114. Referring to FIG. 1, the height of Schottky metal layer 130 extends from H1 to H2, and the height of light emitting layer 114 extends from H3 to H4, where a height HO of the bottom surface of micro LED element 100 serves as a reference height. Accordingly, heights H1 to H4 are arbitrarily defined relative to reference height H0 of the bottom surface of micro LED element 100. The height of Schottky metal layer 130 extending from H1 to H2 spans across the height of light emitting layer 114 from H3 to H4. In other examples, the heights can be defined relative to a different reference height. For example, the heights can instead be defined relative to the bottom surface of second semiconductor layer 113 as an arbitrary reference height. The present disclosure is not limited by the manner in which heights of layers are defined, as long as the heights are measured relative to the same reference height.

Furthermore, the height of Schottky metal layer 130 from H1 to H2 can also span across at least a part of the height of first semiconductor layer 111, low doped layer 115, and second semiconductor layer 113. This arrangement will further facilitate the deposition process of Schottky metal layer 130 and ensure that Schottky metal is deposited on exposed surface 116. The deposition of Schottky metal layer 130 in a relatively larger area instead of depositing merely on exposed surface 116 also provides a possibility of connecting Schottky metal layer 130 among different micro LED elements 100 of a micro LED display panel. A person of ordinary skill would understand that Schottky metal can be used to create a depletion region in a semiconductor, which is a nature of the Schottky metal, which is not further described in the present disclosure.

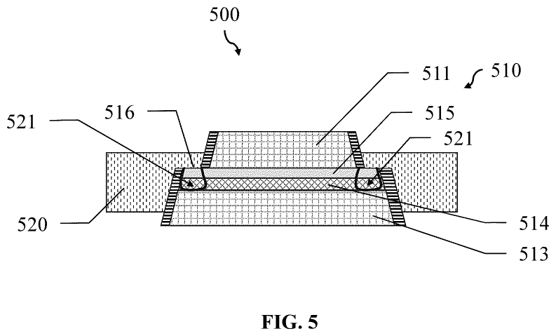

In some examples, Schottky metal layer 130 can be an N-type Schottky metal, such that a negative voltage can optionally be applied to further deplete electrons in depletion region 191. FIG. 5 illustrates a structural diagram showing a sectional view of an exemplary micro LED element illustrating a depletion region, according to some embodiments of the present disclosure. As shown in FIG. 5, a micro LED element 500 includes a mesa 510. Mesa 510 includes a first semiconductor layer 511, a low doped layer 515, a light emitting layer 514, and a second semiconductor layer 513. In some examples, first semiconductor layer 511 is an N-type epitaxial layer and second semiconductor layer 513 is a P-type epitaxial layer. A Schottky metal layer 520 is disposed on an exposed surface 516 and other places. Schottky metal layer 520 is an N-type Schottky metal and not biased by a negative voltage. Whether or not a negative voltage is applied, a depletion region 521 created by Schottky metal layer 520 will repel electrons in light emitting layer 514 at least at the mesa 510 edge. Hence, the introduction of depletion region 521 decreases the probability of electrons reaching the mesa 110 edge to recombine with holes, which decreases non-radiative recombination. The non-radiative recombination in light emitting layer 514 will decrease significantly, thereby increasing the efficiency of micro LED element 500 and decreasing undesirable thermal affects. In other examples, Schottky metal layer 130 (FIG. 1) can be a P-type Schottky metal, and a positive voltage can optionally be applied to deplete holes in depletion region 191. For example, referring again to FIG. 5, if Schottky metal layer 520 is a P-type Schottky metal, a positive voltage can optionally be applied to P-type Schottky metal Schottky metal layer 520. Whether or not a positive voltage is applied, depletion region 521 created by P-type Schottky metal layer 520 will repel holes from light emitting layer 514 at the mesa 510 edge. When a positive voltage is optionally applied to P-type Schottky metal layer 520, depletion region 521 will be enlarged towards second semiconductor layer 513 compared with not applying with a positive voltage.

In some examples, first semiconductor layer 511 is a P-type epitaxial layer and second semiconductor layer 513 is a N-type epitaxial layer. A Schottky metal layer 520 is disposed on exposed surface 516 and other places. If Schottky metal layer 520 is N-type Schottky metal, a depletion region 521 created by Schottky metal layer 520 will repel electrons from light emitting layer 514 at least at the mesa 510 edge. Hence, the introduction of depletion region 521 decreases the probability of electrons reaching the mesa 510 edge to recombine with holes, which decreases non-radiative recombination. The non-radiative recombination in light emitting layer 514 will decrease significantly, which will increase the efficiency of micro LED element 500 and decrease unexpected thermal affects. When a negative voltage is applied to Schottky metal layer 520 provided as N-type Schottky metal, depletion region 521 will be enlarged towards second semiconductor layer 513 compared with not applying a negative voltage. In other examples, Schottky metal layer 520 can be P-type Schottky metal and not biased by a positive voltage, and depletion region 521 created by Schottky metal layer 520 will repel holes from light emitting layer 514 at the mesa 510 edge.

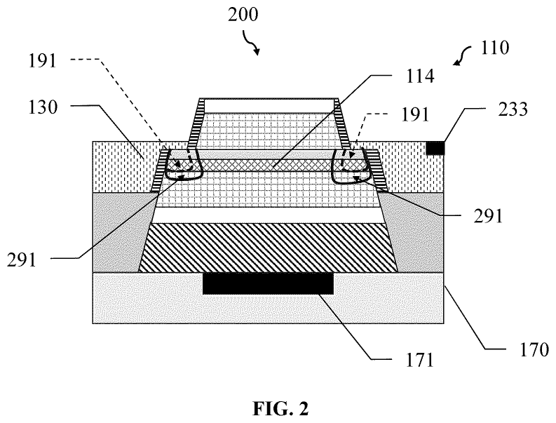

FIG. 2 illustrates a structural diagram showing a sectional view of an exemplary micro LED element 200, according to some embodiments of the present disclosure. Micro LED element 200 in FIG. 2 shares some common components with micro LED element 100 in FIG. 1, and the reference numbers of these components are omitted for simplicity.

As shown in FIG. 2, micro LED element 200 further includes a bias electrode 233 contacting Schottky metal layer 130. As described in conjunction with FIG. 5 above, a negative or positive voltage (also referred to as a bias voltage) can be applied to Schottky metal layer 130 via bias electrode 233 to increase depletion region width. For example, depletion region 191 can be expanded to depletion region 291 by applying a bias voltage to Schottky metal layer 130. The expanded depletion region 291 can further reduce the probability of carriers reaching the mesa 110 edge to recombine non-radiatively. Meanwhile, applying a bias voltage to Schottky metal layer 130 may cause additional power consumption by a bias circuit in an integrated circuit (IC) backplane 170. It is noted that bias electrode 233 can be part of Schottky metal layer 130, and a conductive line can be attached thereto. In some embodiments, the bias voltage is in a range of −5V˜+5V.

As described above, when N-type Schottky metal is used, depletion region 191 (when bias voltage is not applied) induced by Schottky metal layer 130 can repel electrons from the mesa 110 edge, especially in light emitting layer 114. Moreover, when biased by a negative voltage, in a case that second semiconductor layer 113 is an N-type epitaxial layer, an expanded depletion region 291 is generated and more effectively repels electrons from the mesa 110 edge.

As also described above, when P-type Schottky metal is used, depletion region 191 (when bias voltage is not applied) induced by Schottky metal layer 130 can repel holes from the mesa 110 edge, especially in light emitting layer 114. Moreover, when biased by a positive voltage, in a case that second semiconductor layer 113 is a P-type epitaxial layer, an expanded depletion region 291 is generated and more effectively repels holes from the mesa 110 edge.

A material of Schottky metal layer 130 can be selected from one or more of W, Au, Ag, Al, Mo, Pd, Ni, Pt, Cr or Ti, in order to form P-type Schottky metal or N-type Schottky metal. In some other embodiments, the material of Schottky metal layer 130 can be any other materials that can be used to create a depletion region.

Referring again to FIG. 1, mesa 110 may include first transparent conductive layer 140 and a metal reflective layer 150 disposed on a substrate that is also referred to as IC backplane 170. IC backplane 170 that includes a contact pad 171 (e.g., a Cu pad) for electrically connecting IC backplane 170 with metal reflective layer 150.

In some other embodiments, the mesa may include a bottom electrical conductive layer (not shown) formed on a bottom surface of the second semiconductor layer, and the metal reflective layer can be disposed on a bottom surface of the bottom electrical conductive layer. Moreover, in some embodiments, the bottom electrical conductive layer includes the first transparent conductive layer described above, and the first transparent conductive layer is formed on the bottom surface of the second semiconductor layer. In some embodiments, the bottom electrical conductive layer can be the first transparent conductive layer described above.

As shown, metal reflective layer 150 is disposed on a top surface of IC backplane 170, and on a bottom surface of first transparent conductive layer 140. To improve light emission efficiency, metal reflective layer 150 is provided to reflect light upwards, as viewed in FIG. 1. Metal reflective layer 150 may be made of Ag, Al, etc., and coated with one or more of Cr, Ni, Pt, Ti, or Au.

With further reference to FIG. 1, first transparent conductive layer 140 is formed on a bottom surface of second semiconductor layer 113, and on a top surface of metal reflective layer 150. First transparent conductive layer 140 allows the emitted light by intermediate layer 112 to pass through, while it electrically connects second semiconductor layer 113 with metal reflective layer 150.

In some embodiments, first transparent conductive layer 140 is provided as a TCO (transparent conductive oxide) layer, for example, an ITO (Indium Tin Oxide) layer, an AZO (Aluminium doped Zinc Oxide) layer, a GZO (Gallium doped Zinc Oxide), an ATO (Antimony doped Tin Oxide) layer, an FTO (Fluorine doped Tin Oxide) layer, or the like.

With further reference to FIG. 1, micro LED element 100 includes an insulating layer 180 formed over IC backplane 170. Insulating layer 180 covers IC backplane 170 and provides insulation over surface components of IC backplane 170. In addition, Schottky metal layer 130 can be deposited on the surface of insulating layer 180.

With further reference to FIG. 1, Micro LED element 100 may further include a second transparent conductive layer 160 formed on a top surface of mesa 110. More particularly, second transparent conductive layer 160 is formed on the top surface of first semiconductor layer 111 and surrounded by passivation layer 120. Second transparent conductive layer 160 is formed with the same material as first transparent conductive layer 140.

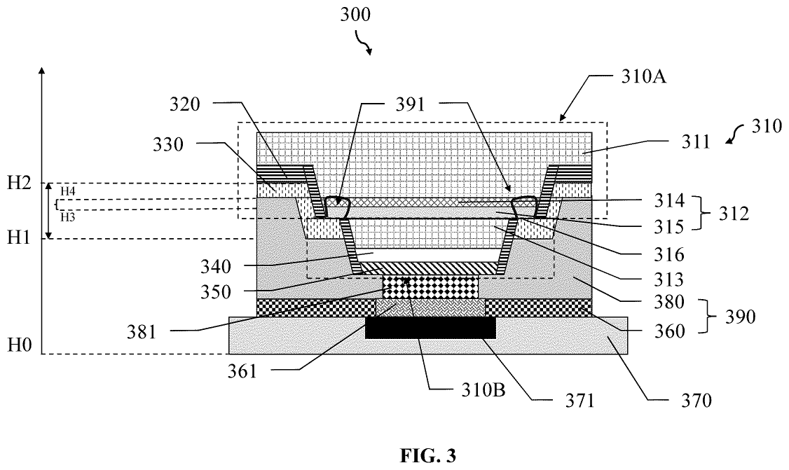

FIG. 3 illustrates a structural diagram showing a sectional view of an exemplary micro LED element 300, according to some embodiments of the present disclosure. Unless otherwise stated or emphasized, the component with the same name or a like reference number here are utilized for the same purpose as those in FIGS. 1 and 2.

Referring to FIG. 3, micro LED element 300 includes a mesa 310, which includes a first semiconductor layer 311, an intermediate layer 312, and a second semiconductor layer 313. First semiconductor layer 311, intermediate layer 312, and second semiconductor layer 313 are stacked from top down to form mesa 310. As can be seen from FIG. 3, mesa 310 includes two stages. A first stage 310A includes first semiconductor layer 311 and intermediate layer 312, and a second stage 310B includes second semiconductor layer 313. The interface between first stage 310A and second stage 310B is the bottom surface of intermediate layer 312. As can be appreciated, first stage 310A and second stage 310B have substantially different cross-sectional sizes at the interface.

As shown in FIG. 3, intermediate layer 312 includes a light emitting layer 314 and a third semiconductor layer also referred to herein as a low doped layer 315. The stacking order of light emitting layer 314 and low doped layer 315 between first semiconductor layer 311 and second semiconductor layer 313 can be varied according to actual needs. To avoid direct exposure to the outside, light emitting layer 314 can be covered by low doped layer 315, as viewed from the outside. That is, a surface of low doped layer 315 plays the role of the interface, as mentioned above. As low doped layer 315 is disposed on a surface of light emitting layer 314 (i.e., on a bottom surface of light emitting layer 314 as shown in FIG. 3), a portion of low doped layer 315 is exposed on the outside of mesa 310 as viewed from below mesa 310 to have a downward (vertical) facing exposed surface 316 relative to mesa 310. A width of exposed surface 316 can be between 0.2 μm to 10 μm. The vertical direction relative to mesa 310 is also an upward direction in which light from light emitting layer 314 is intended to be emitted, as viewed in FIG. 3. Low doped layer 315 has the same doping type as second semiconductor layer 313, and low doped layer 315 has a lower doping concentration than second semiconductor layer 313. In some examples, if second semiconductor layer 313 is an N-type layer formed by doping Si substrate with a doping concentration of 10¹⁸/cm³, then low doped layer 315 can be an N-type layer formed by doping Si substrate with a doping concentration of 10¹⁷/cm³ or lower. Other aspects of low doped layer 315 are the same as those of low doped layer 115 described above, and are not repeated here.

As can be seen in FIG. 3, a sidewall of mesa 310 is inclined. In some embodiments, referring to FIG. 3, a diameter of a top surface of mesa 310 is greater than a diameter of a bottom surface of mesa 310. A cross-sectional size of mesa 310 increases with increasing height of mesa 310 at each of the two stages 310A and 310B. That is, the sidewall of mesa 310 inclines so that mesa 310 gradually becomes broader from bottom to top at each stage.

As mesa 310 can be formed by etching at certain angles, the width of different layers will be different due to the etching mechanism. In an etching process (mesa 310 can be etched while inverted), so that the upper layers (or upper stage) are etched to be narrower than the lower layers (or lower stage).

Still referring to FIG. 3, mesa 310 further includes a transparent conductive layer 340 and a metal reflective layer 350. Second semiconductor layer 313 is formed on a top surface of transparent conductive layer 340. Intermediate layer 312 is formed on second semiconductor layer 313, and first semiconductor layer 311 is formed on intermediate layer 312. During a process of manufacturing an array of micro LED elements 300, first semiconductor layer 311 of each micro LED element 300 can be formed in a single process as so to form a whole and connected layer for the array, wherein this layer can be connected to a common signal and controlled thereby. Other aspects of first semiconductor layer 311, intermediate layer 312, and second semiconductor layer 313 are the same as those of first semiconductor layer 111, intermediate layer 112, and second semiconductor layer 113 described above, and are not repeated here.

Metal reflective layer 350 is provided to reflect light upward, as viewed in FIG. 3. Metal reflective layer 350 may be made composed and coated as described above for metal reflective layer 150.

Micro LED element 300 further includes a passivation layer 320 formed on a sidewall surface of mesa 310, at each of two stages 310A and 310B. Other aspects of passivation layer 320 are the same as those of passivation layer 120 described above, and are not repeated here.

Micro LED element 300 further includes a Schottky metal layer 330 disposed on exposed surface 316. Schottky metal layer 330 can create a depletion region 391 in light emitting layer 314 that may extend into other layers, as described below. In FIG. 3, depletion region 391 covers an edge of mesa 310 in light emitting layer 314. Depletion region 391 is also created in part of low doped layer 315. In some cases, Schottky metal layer 330 can be of the same type (e.g., N-type, P-type) as first semiconductor layer 311. In this situation, Schottky metal layer 330 can be further biased by a voltage, which will be described below. In some other cases, Schottky metal layer 330 can be of a different type than first semiconductor layer 311. In this situation, Schottky metal layer 130 may not be biased.

Although Schottky metal layer 330 disposed on exposed surface 316 is sufficient to create depletion region 391, as shown in FIG. 3, Schottky metal layer 330 can be further disposed on a surface of passivation layer 320, for depositing Schottky metal layer 330 in a more practical process. Specifically, the height of Schottky metal layer 330 spans across at least a part of the height of light emitting layer 314. Referring to FIG. 3, the height of Schottky metal layer 330 extends from H1 to H2, and the height of light emitting layer 314 extends from H3 to H4, where a height H0 of the bottom surface of micro LED element 300 serves as a reference height. Accordingly, heights H1 to H4 in FIG. 3 are arbitrarily defined relative to reference height HO of the bottom surface of micro LED element 300. The height of Schottky metal layer 330 extending from H1 to H2 spans across the height of light emitting layer 314 from H3 to H4. In other examples, the heights can be defined relative to a different reference height. For example, the heights can instead be defined relative to the bottom surface of second semiconductor layer 313 as an arbitrary reference height. The present disclosure is not limited by the manner in which heights of layers are defined, as long as the heights are measured relative to the same reference height.

Furthermore, the height of Schottky metal layer 330 from H1 to H2 can also span across at least a part of the height of first semiconductor layer 311, low doped layer 315, and second semiconductor layer 313. This arrangement will further reduce the difficulty of the deposition process of Schottky metal layer 330 and ensure that Schottky metal is deposited on exposed surface 316.

In some examples, first semiconductor layer 311 is an N-type epitaxial layer and second semiconductor layer 313 is a P-type epitaxial layer. Schottky metal layer 330 can be N-type Schottky metal, and in this situation a negative voltage can optionally be applied to deplete electrons in depletion region 391. Depletion region 391 created by Schottky metal layer 330 will repel electrons from light emitting layer 314 at least at the mesa 310 edge. Hence, the introduction of depletion region 391 decreases the probability of electrons reaching the mesa 310 edge to recombine with holes, which decreases non-radiative recombination. The non-radiative recombination in light emitting layer 314 will decrease significantly, thereby increasing the efficiency of micro LED element 300 and decreasing undesirable thermal affects. When a negative voltage is applied to Schottky metal layer 330, depletion region 391 will be enlarged towards first semiconductor layer 311 compared with not applying with a negative voltage. In other examples, Schottky metal layer 330 can be a P-type Schottky metal and not biased by a positive voltage, which results in depletion region 391 created by Schottky metal layer 330 that repels holes from light emitting layer 314 at the mesa 310 edge.

In some examples, first semiconductor layer 311 is a P-type epitaxial layer and second semiconductor layer 313 is a N-type epitaxial layer. A similar configuration of Schottky metal layer 330 and its biased voltage (if any) can be formed with reference to the above examples, the preset disclosure does not repeat here for abbreviation.

In other examples, Schottky metal layer 330 can be P-type Schottky metal, in this situation a positive voltage can be used to deplete holes in depletion region 391.

Still referring to FIG. 3, first semiconductor layer 311 further includes a first sub-layer formed on light emitting layer 314, and a second sub-layer formed on the first sub-layer. The second sub-layer is continuously formed on passivation layer 320 by covering it. The first sub-layer and the second sub-layer can be formed in a single process and may appear to be the same material. As can be appreciated, the first sub-layer and the second sub-layer are separately described here for explanation of the present disclosure. In some embodiments, first semiconductor layer 311, intermediate layer 312, and second semiconductor layer 313 can be formed in a growing process with different conditions. A part of first semiconductor layer 311 can be etched to form the first sub-layer and an un-etched part of first semiconductor layer is formed as the second sub-layer. Furthermore, in some embodiments, the second sub-layers of different LED elements 300 can be interconnected. For example, the second sub-layers of different LED elements 300 can be continuously formed, without being broken or interrupted in a whole micro LED array area.

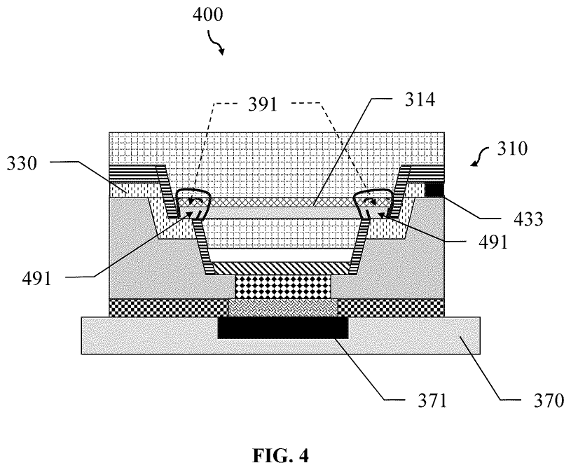

FIG. 4 illustrates a structural diagram showing a sectional view of an exemplary micro LED element 400, according to some embodiments of the present disclosure. Micro LED element 400 in FIG. 4 shares some common components with micro LED element 300 in FIG. 3, and the reference numbers of these components are omitted for simplicity.

As shown in FIG. 4, micro LED element 400 further includes a bias electrode 433 contacting Schottky metal layer 330. As described in conjunction with FIG. 5 above, a negative or positive voltage (also referred to as a bias voltage) can be applied to Schottky metal layer 330 via bias electrode 433 to increase depletion region width. For example, depletion region 391 can be expanded to depletion region 491 by applying a bias voltage to Schottky metal layer 330. The expanded depletion region 491 can further reduce the probability of carriers reaching the mesa 310 edge to recombine non-radiatively. Meanwhile, applying a bias voltage to Schottky metal layer 330 may cause additional power consumption by a bias circuit in an integrated circuit (IC) backplane 370. It is noted that bias electrode 433 can be part of Schottky metal layer 330, and a conductive line can be attached thereto. In some embodiments, the bias voltage is in a range of −5V˜+5V.

As described above, when N-type Schottky metal is used, the depletion region 391 (when bias voltage is not applied) induced by Schottky metal layer 330 can repel electrons from the mesa 310 edge especially in light emitting layer 314. Moreover, when biased by a negative voltage in case that first semiconductor layer 311 is an N-type epitaxial layer, an expanded depletion region 491 is generated more effectively repels electrons from the mesa 310 edge.

As also described above, when P-type Schottky metal is used, the depletion region 391 (when bias voltage is not applied) induced by Schottky metal layer 330 can repel holes from the mesa 310 edge, especially in light emitting layer 314. Moreover, when biased by a positive voltage in case that first semiconductor layer 311 is a P-type epitaxial layer, an expanded depletion region 491 can be generated and more effectively repels holes from the mesa 310 edge.

A material of Schottky metal layer 330 can be selected from one or more of W, Au, Ag, Al, Mo, Pd, Ni, Pt, Cr or Ti, in order to form P-type Schottky metal or N-type Schottky metal. In some other embodiments, the material of Schottky metal layer 330 can be any other materials that can be used to create a depletion region.

Referring again to FIG. 3, micro LED element 300 includes an insulating layer 390 formed on an IC backplane 370 and surrounding mesa 310. In some embodiments, insulating layer 390 may further include a first insulating layer 360 formed on IC backplane 370, and a second insulating layer 380 formed surrounding mesa 310. In some embodiments, first insulating layer 360 and second insulating layer 380 are bonded. A contact pad 361 is embedded in first insulating layer 360 and a contact pad 371 is embedded in IC backplane 370. A contact pad 381 is embedded in second insulating layer 380 for electrically connecting transparent conductive layer 340, metal reflective layer 350, and contact pads 381, 361, and 371, such that second semiconductor layer 313 can be electrically connected with IC backplane 370 and controlled thereby. In some other embodiments, insulating layer 390 can be a single layer, and a single contact pad can be embedded in insulating layer 390 to replace contact pads 361 and 381 for the electrical connection purpose as described above.

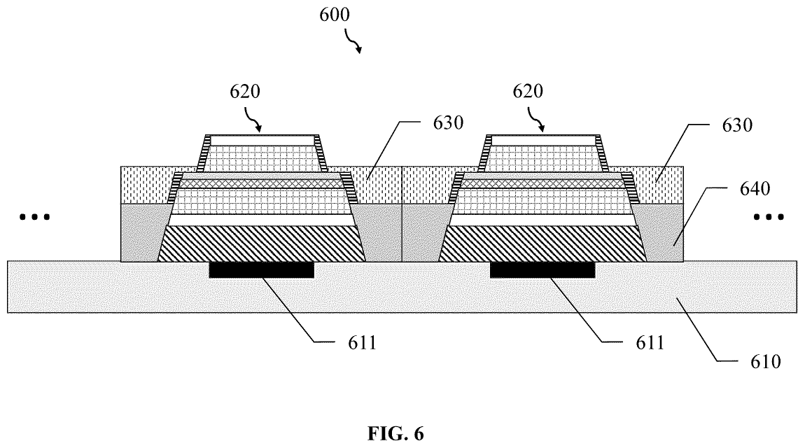

FIG. 6 illustrates a structural diagram showing a sectional view of an exemplary micro LED display panel 600, according to some embodiments of the present disclosure. As shown in FIG. 6, micro LED display panel 600 includes an integrated circuit (IC) backplane 610 (e.g., corresponding to IC backplane 170 in FIGS. 1 and 2, or IC backplane 370 in FIGS. 3 and 4). A plurality of bottom pads 611 (e.g., corresponding to contact pad 171 in FIGS. 1 and 2, or contact pad 371 in FIGS. 3 and 4) are embedded in IC backplane 610 such that one bottom pad corresponds to one micro LED element 620.

Micro LED display panel 600 further includes a plurality of micro LED elements 620 (e.g., corresponding to micro LED element 100 in FIG. 1, micro LED element 200 in FIG. 2, micro LED element 300 in FIG. 3, or micro LED element 400 in FIG. 4). Each of the plurality of micro LED elements 620 is disposed on a side of IC backplane 610. A Schottky metal layer 630 (e.g., corresponding to Schottky metal layer 130 in FIGS. 1 and 2, or Schottky metal layer 330 in FIGS. 3 and 4) of each of the plurality of micro LED elements 620 is electrically connected to the Schottky metal layers 630 of the other micro LED elements 620. In some examples, Schottky metal layer 630 is deposited in a single process, so the deposited layer is contiguous. Moreover, the connected Schottky metal layer 630 is more easily connectable to a bias voltage source. One or more electrodes connected to Schottky metal layer 630 would be sufficient to provide a bias voltage thereto. It can be understood that in FIG. 6, micro LED display panel 600 including two micro LED elements is shown only for illustrative purposes, and the structure can be extended to form a complete micro LED display panel 600. Micro LED display panel 600 further includes an insulating layer 640 formed on IC backplane 610 between each of the plurality of micro LED elements 620. Insulating layer 640 covers IC backplane 610 and provides insulation to surface components of IC backplane 610. In addition, Schottky metal layer 630 can be deposited on the surface of insulating layer 640.

Some embodiments of the present disclosure provide a micro LED display panel. The LED display panel includes an integrated circuit (IC) backplane, a plurality of micro LED elements disposed on a top surface of the IC backplane, an insulating layer, and a Schottky metal layer. In the present disclosure, the top surface of the IC backplane is a surface that the IC backplane can be provided as a substrate for arranging components. As can be appreciated, the top surface, or its corresponding bottom surface on the opposite side, is typically larger than other sides of the IC backplane.

Each of the plurality of micro LED elements includes a mesa and a passivation layer. The mesa includes a first semiconductor layer, an intermediate layer, and a second semiconductor layer which are stacked from top down. The mesa is divided into two stages at a side of the intermediate layer, and the intermediate layer includes a light emitting layer and a low doped layer. The low doped layer is disposed on a surface of the light emitting layer, wherein the low doped layer is exposed to the outside of the mesa in a direction vertical to the mesa with an exposed surface. The passivation layer is formed on the sidewall surface of the mesa. The insulating layer is formed on the side of the IC backplane between each of the plurality of micro LED elements. The Schottky metal layer is disposed on the exposed surface, on the insulating layer, and on a surface of the passivation layer of each of the plurality of micro LED elements. By such arrangement, the Schottky metal layer creates a depletion region at least in the light emitting layer of each of the plurality of micro LED elements.

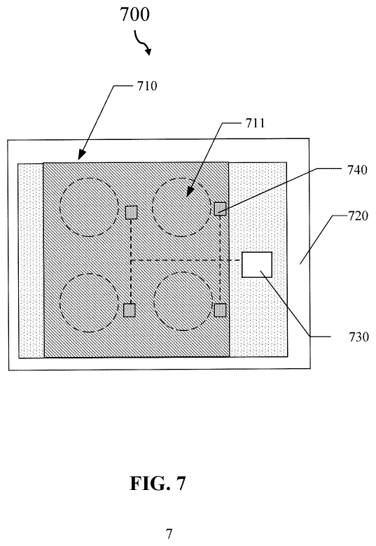

FIG. 7 illustrates a structural diagram showing a top view of a micro LED display panel 700, according to some embodiments of the present disclosure. Referring to FIG. 7, micro LED display panel 700 includes a micro LED array area 710 and an IC (integrated circuit) backplane 720 (e.g., corresponding to IC backplane 170 in FIGS. 1 and 2, or IC backplane 370 in FIGS. 3 and 4). Micro LED array area 710 is located on IC backplane 720 to form an image display area of micro LED display panel 700. The rest of the area on IC backplane 720 not covered by micro LED array area 710 is formed as a non-functional area. IC backplane 720 is formed at the back surface of micro LED array area 710 with a part extending outside of, i.e., not covered by, micro LED array area 710. Micro LED array area 710 includes a plurality of micro LED elements 711 (e.g., corresponding to micro LED element 100 in FIG. 1, micro LED element 200 in FIG. 2, micro LED element 300 in FIG. 3, or micro LED element 400 in FIG. 4) provided in an array. It can be understood that in FIG. 7, micro LED array area 710 including 2×2 micro LED elements is shown only for illustrative purposes. IC backplane 720 is configured to control the plurality of micro LED elements 711. For example, IC backplane 720 can drive the plurality of micro LED elements 711 to display an image. IC backplane 720 may include a bottom pad array (not shown) corresponding to micro LED array area 710. The bottom pad array includes a plurality of bottom pads (e.g., corresponding to contact pad 171 in FIGS. 1 and 2, or contact pad 371 in FIGS. 3 and 4) such that one bottom pad corresponds to one micro LED element 711. One micro LED element of the plurality of micro LED elements is electrically connected with one bottom pad of the plurality bottom pads. Each micro LED element 711 may include a bias electrode 740 (e.g., corresponding to bias electrode 233 in FIG. 2, or bias electrode 433 in FIG. 4), such that one bias electrode 740 corresponds to one micro LED element 711. Bias electrodes 740 can be connected to a common bias voltage (not shown) for realizing an expanded depletion region in the light emitting layer of each micro LED element 711. Bias electrodes 740 can be connected to a bias circuit 730 in IC backplane 720 for realizing an expanded depletion region in the light emitting layer of each micro LED element 711. In some examples, the number of bias electrodes 740 can be less than the number of micro LED elements 711 since the Schottky metal layer of different micro LED elements 711 can be electrically connected. That is, some micro LED elements 711 may not include a corresponding bias electrode 740. Theoretically, one or more bias electrodes 740 is enough for connecting to a common bias voltage. Bias circuit 730 provides a common bias voltage to bias electrodes 740.

Each micro LED element 711 herein has a very small volume. The light emitting area of the micro LED display panel, e.g., micro LED display panel 700 is very small, such as 1 mm×1 mm, 3 mm×5 mm, etc. In some embodiments, the light emitting area of micro LED display panel 700 can be less than or equal to or near 0.15 cm², 0.25 cm², or 1 cm². In some embodiments, the light emitting area is the area of the micro LED array area in the micro LED display panel. Micro LED display panel 700 includes one or more micro LED element 711 that form a pixel array in which the micro LED elements are pixels, such as a 1600×1200, 680×480, or 1920×1080-pixel array. The diameter of each micro LED is in the range of about 200 nm to 2 μm.

Different types of micro LED panels can be provided. For example, the resolution of a display panel can range typically from 8×8 to 3840×2160. Common display resolutions include QVGA (Quarter Video Graphics Array) with 320×240 resolution and an aspect ratio of 4:3, XGA (Extended Graphics Array) with 1024×768 resolution and an aspect ratio of 4:3, D (Definition) with 1280×720 resolution and an aspect ratio of 16:9, FHD (Full High Definition) with 1920×1080 resolution and an aspect ratio of 16:9, UHD (Ultra High Definition) with 3840×2160 resolution and an aspect ratio of 16:9, and 4K with 4096×2160 resolution. There can also be a wide variety of pixel sizes, ranging from sub-micron and below to 10 mm and above. The size of the overall display region can also vary widely, ranging from diagonals as small as tens of microns or less up to hundreds of inches or more.

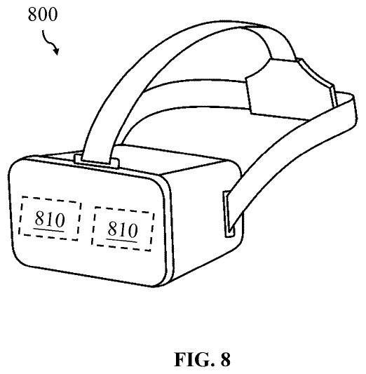

FIG. 8 illustrates an exemplary display device, according to some embodiments of the present disclosure. As shown in FIG. 8, a head-mounted virtual reality device 800 includes two micro LED panels 810 (e.g., corresponding to micro LED display panel 600 in FIG. 6, or micro LED display panel 700 in FIG. 7). Although not shown, head-mounted virtual reality device 800 may also include a central processing unit (CPU), a graphic processing unit (GPU) acting as a signal source, and other related circuit. The introduction of micro LED panels that embody the micro LED elements described above in head-mounted virtual reality device 800 will improve the lighting efficiency therein, hence reducing energy consumption and improving imaging quality.

It should be noted that the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED element, comprising:
a mesa comprising a first semiconductor layer, an intermediate layer, and a second semiconductor layer stacked from top down, wherein the mesa is divided into two stages at a side of the intermediate layer, the intermediate layer comprising:
a light emitting layer; and
a third semiconductor layer disposed on a surface of the light emitting layer, wherein the third semiconductor layer is exposed to an outside of the mesa to have an exposed surface relative to the mesa; and
a Schottky metal layer disposed on the exposed surface, wherein the Schottky metal layer creates a depletion region in the light emitting layer.

2. The micro LED element according to claim 1, wherein a height of the third semiconductor layer is in a range of 5 nm to 50 nm.

3. The micro LED element according to claim 1, further comprising a passivation layer formed on a sidewall surface of each of the two stages of the mesa; wherein,
the Schottky metal layer is further disposed on a surface of the passivation layer.

4. The micro LED element according to claim 3, wherein a height of the Schottky metal layer further spans across at least a part of a height of the light emitting layer.

5. The micro LED element according to claim 4, wherein the height of the Schottky metal layer further spans across at least a part of: a height of the first semiconductor layer, the third semiconductor layer, or the second semiconductor layer.

6. The micro LED element according to claim 5, further comprising a bias electrode contacting the Schottky metal layer.

7. The micro LED element according to claim 3, wherein a thickness of the passivation layer is in a range of 10 nm to 200 nm.

8. The micro LED element according to claim 3, wherein the passivation layer is an ALD (Atomic Layer Deposition)-based layer.

9. The micro LED element according to claim 1, wherein a material of the Schottky metal layer is selected from one or more of W, Au, Ag, Al, Mo, Pd, Ni, Pt, Cr or Ti.

10. The micro LED element according to claim 1, wherein the mesa further comprises a bottom electrical conductive layer formed on a bottom surface of the second semiconductor layer.

11. The micro LED element according to claim 10, wherein the mesa further comprises a metal reflective layer disposed on a bottom surface of the bottom electrical conductive layer.

12. The micro LED element according to claim 10, wherein the bottom electrical conductive layer further comprises a first transparent conductive layer formed on a bottom surface of the second semiconductor layer.

13. The micro LED element according to claim 12, wherein the mesa further comprises a metal reflective layer disposed on a bottom surface of the first transparent conductive layer.

14. The micro LED element according to claim 1, wherein a size of the mesa decreases with a height of the mesa, and the third semiconductor layer disposed on a top surface of the light emitting layer.

15. The micro LED element according to claim 14, further comprising a second transparent conductive layer formed on a top surface of the mesa.

16. The micro LED element according to claim 14, wherein the third semiconductor layer has a same doping type as the first semiconductor layer and a lower doping concentration than the first semiconductor layer.

17. The micro LED element according to claim 1, wherein a size of the mesa increases with a height of the mesa, and the third semiconductor layer is disposed on a bottom surface of the light emitting layer.

18. The micro LED element according to claim 17, wherein the third semiconductor has a same doping type as the second semiconductor layer and a lower doping concentration than the second semiconductor layer.

19. A micro LED display panel, comprising:
an integrated circuit (IC) backplane; and
a plurality of micro LED elements, each of the plurality of micro LED elements comprising:
a mesa comprising a first semiconductor layer, an intermediate layer, and a second semiconductor layer stacked from top down, wherein the mesa is divided into two stages at a side of the intermediate layer, the intermediate layer comprising:
a light emitting layer; and
a third semiconductor layer disposed on a surface of the light emitting layer, wherein the third semiconductor layer is exposed to an outside of the mesa to have an exposed surface relative to the mesa; and
a Schottky metal layer disposed on the exposed surface, wherein the Schottky metal layer creates a depletion region in the light emitting layer,
wherein each of the plurality of micro LED elements is disposed on a top surface of the IC backplane.

20. The micro LED display panel according to claim 19, wherein the Schottky metal layers of the plurality of micro LED elements are electrically interconnected.

21. The micro LED display panel according to claim 19, wherein the Schottky metal layers of the plurality of micro LED elements are separated from each other.

22. The micro LED display panel according to claim 19, wherein each of the plurality of micro LED elements further comprises a second transparent conductive layer formed on a top surface of the mesa, and the second transparent conductive layers of the plurality of micro LED elements are electrically interconnected.

23. The micro LED display panel according to claim 19, wherein each of the plurality of micro LED elements further comprises a second transparent conductive layer formed on a top surface of the mesa, and the second transparent conductive layers of the plurality of micro LED elements are separate from each other.

24. A micro LED display panel, comprising:
an integrated circuit (IC) backplane;
a plurality of micro LED elements disposed on a top surface of the IC backplane, wherein each of the plurality of micro LED elements comprises:
a mesa comprising a first semiconductor layer, an intermediate layer, and a second semiconductor layer stacked from top down, wherein the mesa is divided into two stages at a side of intermediate layer, and the intermediate layer comprises:
a light emitting layer; and
a third semiconductor layer disposed on a surface of the light emitting layer, wherein the third semiconductor layer is exposed to an outside of the mesa to have an exposed surface relative to the mesa;
a passivation layer formed on a sidewall surface of the mesa; and
an insulating layer formed on the top surface of the IC backplane between each of the plurality of micro LED elements; and
a Schottky metal layer disposed on the exposed surface, on the insulating layer, and a surface of the passivation layer of each of the plurality of micro LED elements, wherein the Schottky metal layer creates a depletion region in the light emitting layer of each of the plurality of micro LED elements.

25. The micro LED display panel according to claim 24, wherein each of the plurality of micro LED elements further comprises a second transparent conductive layer formed on a top surface of the mesa, and the second transparent conductive layers of each of the plurality of micro LED elements are electrically interconnected.

26. The micro LED display panel according to claim 24, wherein each of the plurality of micro LED elements further comprises a second transparent conductive layer formed on a top surface of the mesa, and the second transparent conductive layers of each of the plurality of micro LED elements are separated from each other.

27. A display device comprising a micro LED display panel, the micro LED display panel comprising:
an integrated circuit (IC) backplane; and
a plurality of micro LED elements each of the plurality of micro LED elements comprising:
a mesa comprising a first semiconductor layer, an intermediate layer, and a second semiconductor layer stacked from top down, wherein the mesa is divided into two stages at a side of the intermediate layer, the intermediate layer comprising:
a light emitting layer; and
a third semiconductor layer disposed on a surface of the light emitting layer, wherein the third semiconductor layer is exposed to an outside of the mesa to have an exposed surface relative to the mesa; and
a Schottky metal layer disposed on the exposed surface, wherein the Schottky metal layer creates a depletion region in the light emitting layer,
wherein each of the plurality of micro LED elements is disposed on a top surface of the IC backplane.
